(19) United States
(12) Patent Application Publication
(10) Pub. No.: US 2010/0239916 A1
(43) Pub. Date: Sep. 23, 2010

(54) NON-AQUEOUS ELECTROLYTE AND A BATTERY, A SUPERCAPACITOR, AN ELECTROCHROMIC DEVICE AND A SOLAR CELL INCLUDING SUCH AN ELECTROLYTE

(75) Inventors: Aninda Bhattacharryya, Stuttgart (DE); Joachim Maier, Wiernsheim (DE); Anna Jarosik, Stuttgart (DE)

Correspondence Address: LEWIS AND ROCA LLP, 1663 Hwy 395, Suite 201, Minden, NV, 89423, US

(73) Assignee: Max-Planck-Gesellschaft zur Forderung der Wissenschaften e.V.

(21) Appl. No.: 12/748,649

(22) Filed: Mar. 29, 2010

Related U.S. Application Data
(63) Continuation-in-part of application No. 10/913,959, filed on Aug. 6, 2004, now Pat. No. 7,700,240.

(30) Foreign Application Priority Data
Aug. 8, 2003 (EP) 03018161.4

(51) Int. Cl. H01M 6/14; H01M 10/26; H01L 31/00; H01G 9/00; G02F 1/15

(52) U.S. Cl. 429/300; 429/207; 136/252; 136/255; 361/502; 359/265

(57) ABSTRACT

A non-aqueous electrolyte including at least one ionically conducting salt, especially a lithium salt, a non-aqueous, anhydrous solvent for the ionically conductive salt, and at least one oxide in a particulate form, said oxide being selected such that it is not soluble in said solvent and such that it is water-free. The electrolyte can be used in a primary or secondary lithium battery, in a supercapacitor, in an electro-chromic display or in a solar cell.

### CROSS-REFERENCE TO RELATED APPLICATIONS

This application is a continuation-in-part of co-pending U.S. patent application Ser. No. 10/913,959, filed Aug. 6, 2004, which claims the benefit of European Patent 03 018 161.4, filed Aug. 8, 2003, the entirety of both are incorporated by reference herein.

### BACKGROUND

The present invention relates to a non-aqueous electrolyte and has particular reference to a non-aqueous electrolyte which can be used in a primary or secondary battery, such as a lithium battery, in a supercapacitor, in an electrochromic device or in a solar energy cell. Furthermore, the present invention relates to a non-aqueous electrolyte when used in any of the foregoing devices.

Lithium batteries are known in non-rechargeable and in rechargeable form. Such batteries comprise positive and negative electrodes with a non-aqueous electrolyte disposed between them.

In a rechargeable lithium ion battery (secondary battery) the positive electrode of the battery can for example be LiCoO₂ (referred to as the “cathode” in Li-battery community) and the negative electrode can for example be carbon (referred to as the “anode” in Li-battery community). In a non-rechargeable battery (primary battery) the positive electrode can for example be MnO₂ and the negative electrode can be lithium metal. Various different types of electrolyte are known. For example there is the class of liquid electrolytes comprising at least one ionically conducting salt such as Li(TFSI), i.e. lithium bis(trifluorosulphonyl)imide, LiPF₆, i.e. lithium hexafluorophosphate or LiClO₄, i.e. lithium perchlorate which are present, with a low degree of dissociation within a non-aqueous solvent such as a mixture of DME (dimethylethane) and EC (ethylene carbonate), a mixture of DEC (diethylene carbonate) and EC, or a mixture of DMC (dimethyl carbonate) and EC or PC (propylene carbonate) or combinations thereof.

In addition there are so-called dry polymer electrolytes. In these electrolytes the salt is selected as before (i.e. for example from Li(TFSI), LiPF₆ or LiClO₄) and is dispersed in a polymer or mixture of polymers. Suitable polymers comprise PEO (polyethylene oxide), PVDF (polyvinylene difluoride), PAN (polyacrylonitrile), and PMMA (polymethyl methyl acrylate).

Furthermore, there are so called polymer gel electrolytes. These have the same basic composition as the dry polymer electrolytes recited above but include a solvent, for example a solvent of the kind recited in connection with the liquid electrolytes given above.

The known liquid electrolytes described have the advantage that they have a high ionic conductivity up to a transference number of 6 and a high conductivity of 10⁻² S/cm. In addition the liquid properties ensure good wetting of the electrode surface. They are however dangerous because leakage can occur, so that safety considerations arise. In addition they can lead to passivation effects which are undesirable.

The dry polymer electrolytes do not result in good wetting of the electrodes, the conductivities which can be achieved are quite low and there is also not much scope for modifying the chemical composition of the ingredients. However, the electrolytes are good safety-wise and no leakage occurs.

With the polymer gel electrolytes the change in liquid content results in reductions in the conductivity and there is also the danger of leakage.

The object of the present invention is to provide an electrolyte comprising a lithium salt and a solvent as before but with an improved conductivity.

In order to satisfy this object there is provided, in accordance with the present invention, a non-aqueous electrolyte including
at least one ionically conducting salt, especially a lithium salt,
a non-aqueous, anhydrous solvent for the ionically conductive salt, said solvent being selected to achieve a degree of dissociation of the ionically conductive salt in the non-aqueous solvent,
at least one oxide in a particulate form, said oxide being selected such that it is not soluble in said solvent and such that it is water-free.

The applicants have namely found that the addition of fine oxide particles, e.g. in powder or elongate particle form, leads to a substantial increase in conductivity but with no disadvantages.

The electrolyte preferably has a low degree of dissociation, preferably with association constant in the range from 1×10⁻¹ to 10⁸/l⁻¹·mol⁻¹.

When used in a primary or secondary lithium battery having positive and negative electrodes, the oxide should be selected such that it does not react with the material of either of said positive and negative electrodes.

The non-aqueous electrolyte of the present invention is not restricted to use in a battery, it can for example be used in a supercapacitor, in electrochromic devices such as electro-chromic displays or in a solar energy cell.

In the non-aqueous electrolyte of the invention the ionically conductive salt is selected from the group comprising Li(TFSI), LiPF₆ and LiClO₄.

Moreover, the non-aqueous, anhydrous solvent is preferably selected from the group comprising DEC/EC, DMC/EC, PC, carbonate based solvents related to any of the foregoing, DMSO, organic sulphur compounds, THF, AN and mixtures of any of the foregoing.

The oxide used for the invention is preferably selected from the group comprising oxides exhibiting acidic properties, for example SiO₂, TiO₂ and oxides exhibiting basic properties, for example Al₂O₃, MgO and any mixtures thereof.

The average particle size of the oxide for particles of approximately spherical shape, is selected to be less than 5 μm and preferably less than 2 μm, with no lower limit other than that set by manufacturing techniques used to produce said oxide. For elongate particles, such as nano-wires or nano-tubes, the average diameter is selected to be less than 1 μm, preferably less than 100 nm, there being no limit on the length of such elongate particles.

The amount of oxide present in the electrolyte is preferably such as to give the electrolyte a consistency between that of a liquid and a solid, preferably a consistency similar to that of a soggy sand, i.e. a liquid and sand mixture having a consistency such that sedimentation effects do not occur.

The invention will now be described in further detail with reference to basic designs of Lithium batteries known in the prior art as shown in FIGS. 1 and 2 and with reference to the results of experiments carried out on examples of electrolytes in accordance with the present invention.

### BRIEF DESCRIPTION OF THE DRAWINGS

FIG. 1 shows a schematic illustration of a conventional lithium-ion battery,

FIG. 2 shows a schematic illustration of an alternative design of a lithium-ion battery,

FIG. 3 shows a plot of composite conductivity versus various oxide volume fractions (particle size (=2r) approx 0.3 μm) at room temperature illustrating how oxide surface acidity/basicity influences the composite conductivity, with the insert showing the influence of particle size on composite conductivity,

FIG. 4 shows a plot of SiO₂/LiClO₄—MeOH and SiO₂/LiClO₄-THF composite conductivity versus SiO₂ fraction (particle size approx. 0.3 μm) for different solvents at room temperature illustrating the ion association in a non-aqueous solution,

FIG. 5 shows the variation of high-conducting layer conductivity in various oxide solution composites versus oxide concentrations expressed as a volume fraction,

FIG. 6 shows a plot with varying ionic conductivity for different concentrations of LiClO₄, and

FIG. 7 shows a plot of composite conductivity versus various oxide volume fractions.

### DETAILED DESCRIPTION

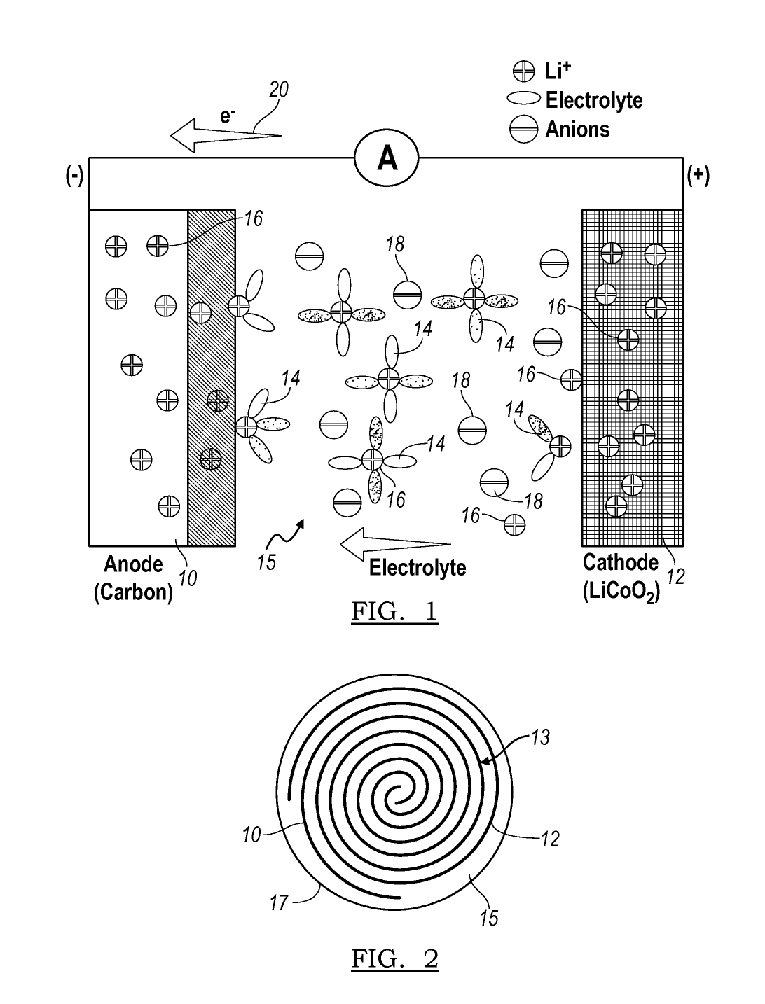

Referring first of all to FIG. 1 there is shown a diagram showing the basic configuration of an Li-ion battery of a kind used for research. It typically comprises an anode (in this case a carbon anode) 10, a cathode 12, in this case LiCoO₂ and an electrolyte 14 disposed in the space between the anode 10 and the cathode 12. Present throughout the volume of the electrolyte 15 are also lithium ions 16 shown as circles with a cross in the middle, and anions 18 shown as larger circles with a single line through the middle. When an external circuit is connected to the battery, current flows in the direction opposite to the arrow 20 during discharging and in the direction of the arrow during charging.

It has already been established by others that transition metal oxides, more specifically the oxides Fe, Ni, Co, Cu, show promising performance as anode materials for rechargeable lithium batteries. The reversible Li-storage mechanism is due to the formation and decomposition of Li₂O upon the electrochemical insertion/extraction of Li. The key point for the reversibility seems to be the formation of a special microstructure in which metal clusters are dispersed uniformly with Li₂O at a nanoscale after electrochemical reaction of metal oxide with Li.

German patent application 102 42 694.5 assigned to the present applicants recognizes that LiF, which is electrochemically inactive, shows electrochemical activity when it is dispersed with a transition metal at atomic or nanoscale level. A series of transition metal fluorides (M═Ti, V, Mn, Fe, Co, Ni, Cu) were investigated and led to favorable results.

The experimental setup was as follows:

The working electrodes comprised either TiF3A:TiF₃:PVDF (9:1) on Ti foil; or TiF3B:TiF₃:CB:GP:PVDF (10:0.5:0.5:1) on Ti foil. CB denotes carbon black, GP denotes graphite and PVDF denotes polyvinylene di-fluoride. The pasting procedures for the electrode film on the Ti-foil are similar to those reported in H. Li. L. H. Shi, W. Lu, X. J. Huang, L. Q. Chen, J. Electrochem. Soc., 148, A915 (2001)

The electrochemical cells tested were 2-electrode cells for electrochemical testing similar in layout to the known cell of FIG. 1 but using the alternative electrodes. It is noted that the electrode materials proposed and claimed in the German patent application 102 42 694.5 can be used as either anodes or cathodes depending on the relative potential difference to the metal lithium. If this potential difference is 2.5 volts or less then the material is considered suitable as an anode material. If the potential difference is 2.5 volts or more then the material is considered suitable as a cathode material.

FIG. 2 shows an alternative layout for a battery where the electrodes 10 and 12 are coiled in a spiral 13 with the electrolyte 15 disposed between them and the structure being encapsulated in a housing 17. Terminals connected to the anode 10 and the cathode 12 are provided at opposite ends of the housing (terminals not shown) in manner known per se. The same layout as shown in and described with reference to FIG. 2 can be used for a supercapacitor.

The materials can be the same as those described with reference to FIG. 1.

Two examples will now be given for the preparation of non-aqueous, anhydrous electrolytes:

### Example 1

The composite electrolyte was prepared in the form of a mixture of fine particles of ceramic oxides (SiO₂, TiO₂ and Al₂O₃, radius: r ˜0.15 μm) with a non-aqueous solution of 0.1M LiClO₄ in Methanol (MeOH). Although MeOH was selected for this test it is not a preferred solvent for lithium batteries. However, because the invention is effective using MeOH it appears certain that it will work better in the preferred solvents, i.e. in a non-aqueous, anhydrous solvent selected from the group comprising DME/EC, DEC/EC, DMC/EC, PC, carbonate based solvents related to any of the foregoing, DMSO, organic sulphur compounds, THF, AN and mixtures of any of the foregoing, and indeed practical tests have confirmed this.

In this example the oxides were dried in vacuum at 250° C. for 24 hours prior to composite preparation and all samples were prepared under an Argon atmosphere in a glove box (closed container with a window and gloves for handling the materials involved). Room temperature conductivity was measured for various volume fractions using impedance spectroscopy with the samples placed between two parallel stainless steel electrodes of a home-built cell (samples loaded under Argon). The impurity effects were excluded by pre-washing the oxides in the liquid solvents. The conductivity was better than 2×10⁻³ S/cm.

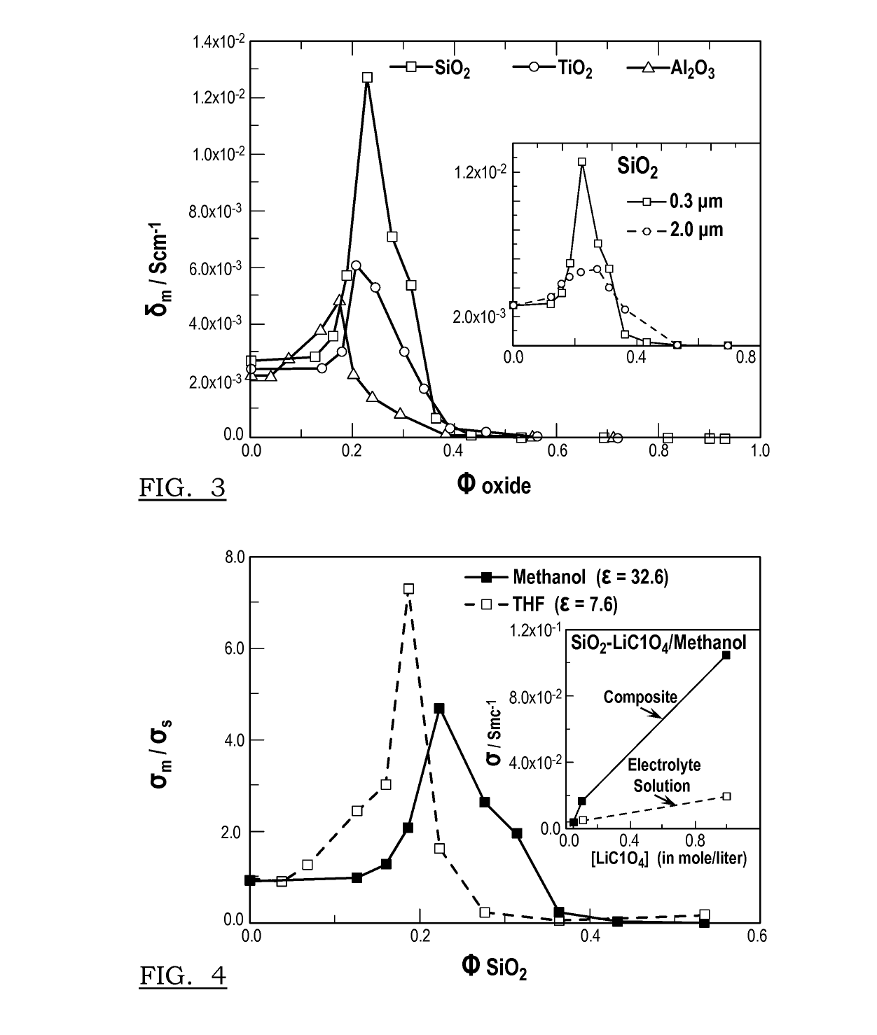

FIG. 3 shows the variation of the effective overall ionic conductivity with volume fraction (φ) for different oxides. As observed for all the oxides, the composite conductivity with oxide volume fraction shows a percolation-type behaviour that is typical for a composite electrolyte with enhanced interfacial conductivity, i.e. low conductivity at low oxide content, a pronounced increase with a marked maximum and subsequent decrease at higher volume fractions. Since in the inorganic solid-solid composite electrolytes the pathways are ordered (Al₂O₃ particles along the grain boundaries), the percolation threshold is normally shifted to lower volume fractions. Composite conductivity is, as FIG. 3 shows, highly influenced by the differing surface acid-base property of the oxides; the conductivity enhancement is higher for the acidic oxides SiO₂, TiO₂ (highest for SiO₂) compared to the more basic Al₂O₃ (pH of point of zero charge (pzc) in aqueous solutions being: 3, 5 and 9 for SiO₂, TiO₂ and Al₂O₃ respectively.

This is interpreted as suggesting that the conductivity enhancement in the liquid-solid composite is attributable to the formation of a highly conducting layer around the oxide filler with a higher Li ion conductivity compared to that in the solution caused by adsorption of the anion and breaking up of the ion-pair. This is also supported by ζ-potential measurements (φ_{oxide}≈5×10⁻⁵, [LiClO4]≈10⁻³M) arising out of the effective surface charge showing a more negative potential measuring from Al₂O₃ (−18.3 mV) to SiO₂ (−36.3 mV). In the regime of lower oxide fractions, i.e. in the colloidal regime, the double layer repulsion works against percolation and leads to the very poor effect in the case of SiO₂. The earlier but smoother increase (lower percolation threshold) in that regime of the Al₂O₃ composite is in agreement with a lower charge density at the Al₂O₃ surface. As soon as the particles are forced to be sufficiently close (Debye length, λ˜100 nm) the interfacial conductivity percolates (in a cubic arrangement the minimal particle-particle distance (δ) is assessed to be 2δ at φ≈6.5%). At this volume fraction range the situation resembles the Nafion-type electrolytes in which the counter ion is attached to the polymer backbone and the proton is mobile within tiny water filled channels. Since the freed counter ion needs solvent to be mobile the conductivity breaks down at higher φ, (in cubic arrangement δ≈0 for φ≈52%). The maximum conductivity enhancement was observed for SiO₂-composite with σₘ=1.2×10⁻² S/cm which is of the order of a high conducting electrolyte used for Li-battery. The interfacial picture is also supported by the fact that the SiO₂ with larger surface area per unit volume, i.e. with an average particle size of 0.3 μm, (inset FIG. 3) is distinctly more active than with an average particle size of 2.0 μm.

### Example 2

The role of the oxides in dissociation of ion-pairs in non-aqueous solution was further investigated by preparing composite electrolytes comprising a solution of an Li-salt in tetrahydrofuran (THF) with added SiO₂. The THF exhibits a significantly lower dielectric constant (∈_{THF}=7.4) compared to MeOH (∈_{MeOH}=32.6). Indeed, as shown in FIG. 4, the THF-composite shows a markedly higher enhancement in conductivity (with lower absolute σ values) compared to the MeOH-composite for similar silica particle size and identical salt concentrations. The degree of ion-association in the case of THF (association constant of LiClO₄ in THF at 298 K is 4.8×10⁷/l⁻¹·mol⁻¹) is apparently higher than MeOH and the impact of the filler is accordingly higher, as is evident from FIG. 4. The fact that percolation starts earlier in the THF case is consistent with the lower ∈ (double repulsion ∝∈) corresponding to a smaller surface charge (see equation 2). The relevance of ion-association was further corroborated by carrying out the experiment at different Li⁺ salt concentration in MeOH, keeping the SiO₂ volume fraction fixed (inset of FIG. 4). As is evident, the conductivity enhancement disappears at high dilution since the association vanishes due to entropy. According to mass action, the degree of dissociation has to approach unity as salt concentration tends to zero.

The effective composite conductivity (σₘ) can be written as follows:

σₘ=βₛφₛσₛ+β₁φ₁Δσ_{m,1} 1)

where φₛ and φ₁ are the volume fractions for solution and high conducting layer respectively whereas σₛ and Δσ_{m,1} are respectively the ionic conductivities for the solution and excess conductivity of the high conducting layer. The β-factors measure the degree of percolation and are of the order of unity for a parallel switching (only percolating pathways). They are distinctly less and depend on φ if this is not the case. Equation (1) leads to the estimate of lower limit of the maximum interfacial conductivity according to

$${Δσ}_{m , 1} > \frac{{σ}_{m} - {σ}_{s} ( 1 - φ )}{φ}$$

which is plotted in FIG. 5 and pronounces even more the differences in the percolation behavior. A further evaluation of the peak conductivity in terms of the space charge effect, requires a more detailed insight into the distribution also with respect to the boundary conditions. The r.h.s. of equation 1 is proportional to

$${uF ( ɛ {Tc}_{o} )}^{\frac{1}{2}}$$

(where u is the mobility of the Li ions, F is the Faraday constant, ∈ is the dielectric constant, T is the absolute temperature and cₒ is the concentration in the first layer adjacent to the adsorption layer) for semi-infinite boundary conditions and large effects while it tends to uFcₒ for a vanishing solution channel width (given a sufficient thickness to maintain mobility).

Since the dielectric constant of CH₃OH is comparable to that of typical Lithium battery electrolytes a marked improvement is expected when using improved “soggy sand” electrolytes of the invention based on electrolytes which are (meta)stable in Li-batteries. The experiments conducted to date give strong evidence for the possibility of enhancing ion transport in non-aqueous solutions by breaking ion-pairs at the interfaces to appropriate second phases. Beyond that they indicate the validity of heterogeneous doping mechanism proposed for inorganic crystals to be operative also for polymer electrolytes.

The experiments conducted provide evidence for the usefulness of composite electrolytes consisting of liquid non-aqueous salt solutions and solid insulating particles. At high second phase contents the investigated system show distinctly enhanced conductivities and are better described as “soggy sand” electrolytes, a viscous grain ensemble wetted by the liquid. Unlike solid-liquid composites described by Amita Chandra and Joachim Maier in Solid State Ionics 148, pages 153 to 158 (2002), the effects are not additive rather they are synergistic in the sense that the overall conductivity is distinctly higher than both of the constituent phases, an effect that is ascribed to interfacial interaction. The “soggy sand” electrolytes of the invention as described above combine enhanced conductivities with the favourable mechanical properties of the soft matter.

Polymer electrolytes under consideration consist of a salt dissolved in a covalent polymer matrix (the cases of polymer electrolytes in which one ion is strongly bound to the polymer (e.g. Nafion) are not expected to exhibit a heterogeneous doping effect as touched upon later). They are materials of prime importance in the context of electrochemical devices. Since the compositional flexibility however is not unlimited, strategies for optimising the conductivity properties of a given conductor are necessary.

In crystalline electrolytes, i.e. influencing the conductivity by adding second phase particles proved very helpful in different cases. Indeed it has been found [Scrosati, Wieczorek] that the dispersion of oxides leads to significant conductivity increases in crystalline electrolytes. Different explanations have been proposed, most of them considering mobility changes owing to segmental motion of the polymers, variation of the degree of crystallinity etc., whereas the effect in composite inorganic electrolytes, to which the present invention is directed, has been essentially attributed to a charge carrier concentration effect.

The heterogeneous doping effect consists of internally adsorbing one ion sort and hence effectively leading to dissociation. In the crystalline state e.g. AgCl:Al₂O₃ this may be the adsorption of Ag⁺ or F⁻ ions connected with its removal from the energetically deep-lying regular positions resulting in the generation of vacancies as mobile carriers. In the covalent matrix the immobile ground state would be the undissociated ion pair with the conductivity effect consisting in the adsorption of one pair constituent resulting in breaking of the ion pair and generating a mobile counter ion as described by J. Maier, Prog. Solid St. Chem. 23 pages 171 to 263 (1995). Testing this hypothesis is rather difficult since a polymer matrix may be different in various ways. It was for this reason that a decision was made to test the effect of oxide additions to a salt in a liquid solvent of low polarity, i.e. MeOH. It was found that the conductivity is significantly enhanced with a percolation behaviour typical for interfacial conductivity and that the different impact of oxides with different basicity points towards a perchlorate adsorption and hence increased Li⁺ conductivity.

To investigate whether percolation type behaviour arises with a pronounced increase in conductivity for low volume fractions of SiO₂, two low molecular solvents were prepared. The following liquid polymers were used:
1) poly(ethylene glycol)dimethyl ether (PEG-150, M_{W}=150 g/mol, water content 0.22%—1453 ppm, σ=4.63·10⁻⁶ Scm⁻³ at T=25° C.) and
2) poly(ethylene glycol) methyl ether (PEG-350, M_{W}=350 g/mol, water content 0.11%—1132 ppm, σ=5.34·10⁻⁷ Scm⁻³ at T=25° C.).

The following properties were obtained for liquid polymers 1) and 2):
i) dielectric constant ∈_{PEG-150}=23.9 and ∈_{PEG-350}=25.2, respectively;
ii) viscosity under constant shear rate equal \dot{γ}=500 s⁻¹ η_{PEG-150}=6.94 cP and η_{PEG-350}=31.2 cP, respectively;
iii) density ρ_{PEG-150}=1.016 g/cm³ and ρ_{PEG-350}=1.106 g/cm³, respectively;

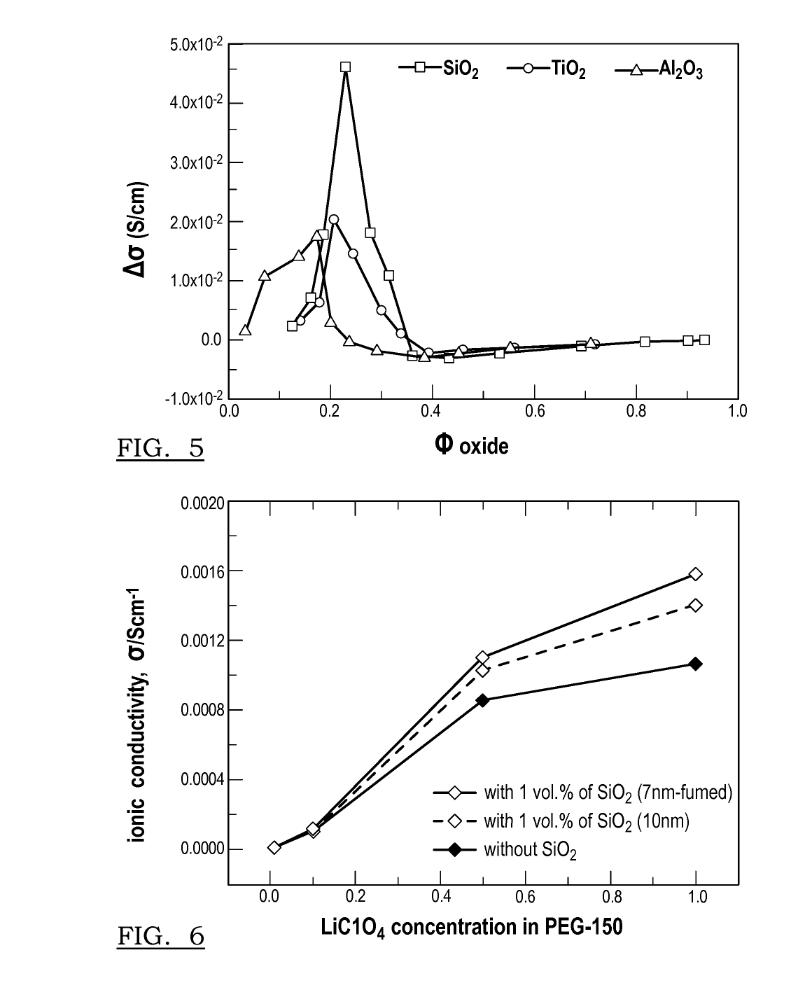

In a first step, the solvents were admixed with different concentrations of lithium salt (LiClO₄). It was discovered that the highest values for the ionic conductivity were found at a concentration of 1 Mol. (see Table 1 below and FIG. 6, respectively). The salt was stirred until it was completely dissolved in the solvent.

TABLE 1

| | | PEG + SiO₂ | PEG + SiO₂ |
|---|---|---|---|
| | PEG-150 | (10 nm) | (7 nm-fumed) |
| PEG-LiClO₄ | σ/Scm⁻¹ | σ/Scm⁻¹ | σ/Scm⁻¹ |
| 0.01 M | 1.048 · 10⁻⁵ | 1.186 · 10⁻⁵ | 1.358 · 10⁻⁵ |
| 0.1 M | 1.058 · 10⁻⁴ | 1.017 · 10⁻⁴ | 1.198 · 10⁻⁴ |
| 0.5 M | 9.55 · 10⁻⁴ | 1.03 · 10⁻³ | 1.109 · 10⁻³ |
| 1 M | 1.07 · 10⁻³ | 1.41 · 10⁻³ | 1.586 · 10⁻³ |

Table 1 shows the changes in ionic conductivity of electrolytes containing a PEG-150 solvent and for different concentrations of LiClO₄, a reference sample of PEG-150 which contained no SiO₂ was compared to samples of PEG-150 containing 1 vol. % SiO₂ (7 nm-fumed SiO₂) and a sample containing 1 vol. % SiO₂ (10 nm grain size), at a steady state after 8 h for each respective lithium salt concentration.

FIG. 6 shows a graph plotted illustrating the change in ionic conductivity based on the data points given Table 1. One can clearly see that for a 1 M concentration of LiClO₄ the solvent including 7 nm fumed SiO₂ has an ionic conductivity which is approximately 50% greater than the ionic conductivity of the electrolyte which contains no oxides. The electrolyte containing 10 nm SiO₂ has an ionic conductivity which is approximately 40% greater than the ionic conductivity of the electrolyte which contains no oxides.

Fumed SiO₂, also known as pyrogenic silica, is a non-crystalline, fine grain, low density and high surface area silica. It is not to be confused with silica fume, which is also known as microsilica. Fumed silica can be produced in a flame pyrolysis procedure, in which silicon tetrachloride or quartz sand is vaporized in an electric arc, at e.g. 3000° C., as is known to the person of ordinary skill in the art. The primary particle size of fumed silica is typically 5 to 50 nm. The fumed silica particles are non-porous and have a surface area of typically 50 to 600 m²·g⁻¹ and a density of 2.2 g·cm⁻³. It has been found that fumed silica with properties in the ranges set out above can be exploited to advantage in a non-aqueous electrolyte in accordance with the present teaching. It should be noted that this does not mean that fumed silica outside the quoted ranges are not useful, they have simply not been investigated.

In a next step, the amount of SiO₂ added to a solvent including 1 M of LiClO₄ were investigated. In particular, different volume fractions of different grain size SiO₂, 7 nm-fumed (water content 0.0%-9.8 ppm) or 10 nm non-fumed (water content 0.03%-281.3 ppm) respectively, in both 1M PEG-150-LiClO₄ and 1M PEG-350-LiClO₄ were investigated. For this the amount of oxide particles added to the solvent (fumed and non-fumed SiO₂), were dried at ˜400° C. for 24 h, under vacuum and stored in a dry glove box under an argon atmosphere (water content approximately 0.1 ppm, before use). Following this the composite electrolytes were prepared by dispersing the SiO₂ in the corresponding LiClO₄/PEG solution using a Vortex shaking device to obtain well dispersed solution. The concentration of the SiO₂ in the composite electrolytes were varied from 0.5 to 20% by volume fraction of SiO₂.

Following the preparation of the sample ionic conductivity was measured under a controlled temperature and a controlled argon flow.

Table 2 below shows different volume fractions of SiO₂ of two different grain sizes, 7 nm-fumed (water content 0.0%-9.8 ppm) or 10 nm (water content 0.03%-281.3 ppm) respectively, in 1M PEG-150-LiClO₄.

TABLE 2

| | 1M LiClO₄-PEG- | 1M LiClO₄-PEG- |
|---|---|---|
| vol. fract | 150:SiO₂(10 nm) | 150:SiO₂(7 nm-fumed) |
| of SiO₂ | σ/Scm⁻¹ | σ/Scm⁻¹ |
| 0 | 1.07 · 10⁻³ | 1.07 · 10⁻³ |
| 0.005 | 1.61 · 10⁻³ | 2.04 · 10⁻³ |
| 0.01 | 1.85 · 10⁻³ | 2.10 · 10⁻³ |
| 0.02 | 1.82 · 10⁻³ | 1.83 · 10⁻³ |
| 0.03 | 1.78 · 10⁻³ | 1.71 · 10⁻³ |
| 0.05 | 1.54 · 10⁻³ | 1.68 · 10⁻³ |
| 0.07 | 1.44 · 10⁻³ | 1.73 · 10⁻³ |
| 0.1 | 1.23 · 10⁻³ | 1.17 · 10⁻³ |
| 0.15 | 5.66 · 10⁻⁴ | 1.09 · 10⁻³ |
| 0.2 | 6.18 · 10⁻⁷ | 7.48 · 10⁻⁶ |

Table 3 below shows the different volume fractions of SiO₂ for different grain sizes, 7 nm-fumed (water content 0.0%-9.8 ppm) or 10 nm (water content 0.03%-281.3 ppm) respectively, in 1M PEG-350-LiClO₄.

TABLE 3

| | 1M LiClO₄-PEG- | 1M LiClO₄-PEG- |
|---|---|---|
| vol. fract | 350:SiO₂(10 nm) | 350:SiO₂(7nm-fumed) |
| of SiO₂ | σ/Scm⁻¹ | σ/Scm⁻¹ |
| 0 | 1.24 · 10⁻⁴ | 1.24 · 10⁻⁴ |
| 0.005 | 3.81 · 10⁻⁴ | 4.02 · 10⁻⁴ |
| 0.01 | 3.46 · 10⁻⁴ | 2.80 · 10⁻⁴ |
| 0.02 | 3.44 · 10⁻⁴ | 3.68 · 10⁻⁴ |
| 0.03 | 3.62 · 10⁻⁴ | 3.61 · 10⁻⁴ |
| 0.04 | 2.998 · 10⁻⁴ | 3.04 · 10⁻⁴ |
| 0.05 | 3.07 · 10⁻⁴ | 3.01 · 10⁻⁴ |
| 0.06 | 2.26 · 10⁻⁴ | 4.35 · 10⁻⁴ |
| 0.07/0.08 | 3.29 · 10⁻⁴ | 1.81 · 10⁻⁴ |
| 0.1 | 2.62 · 10⁻⁴ | 1.31 · 10⁻⁴ |
| 0.15 | 1.37 · 10⁻⁴ | 1.65 · 10⁻⁴ |

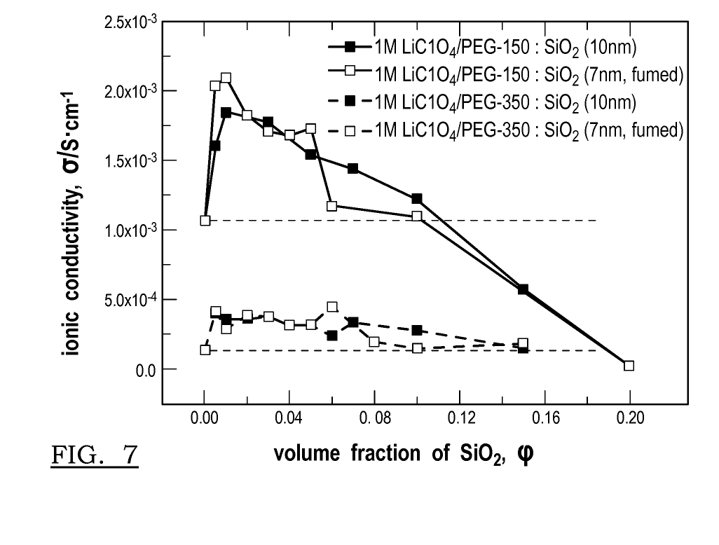

FIG. 7 shows the changes in ionic conductivity for electrolytes containing different volume fractions of SiO₂ (7 nm-fumed and 10 nm grain size) for different solvents (1M PEG-150-LiClO₄ and 1M PEG-350-LiClO₄). One can clearly see that the addition of the respective oxide increases the ionic conductivity of the respective solvent for low volume fractions of SiO₂. In particular, volume fractions in the volume range from 0.5% to 10% have been found to result in increased ionic conductivity values, with the best results being obtained in the range from 0.5% to 6%. Again no separator was necessary between the electrodes of a battery containing the electrolyte containing the oxide.

It was also observed that for solutions containing SiO₂ (especially fumed; non-crystalline, fine-grain, low density and high surface area silica, with higher density of silanol (Si—OH) groups on the surface; where the particles are non-porous and have a surface area of 50-600 m²·g⁻¹), more stable gel-like composite solutions are obtained and separation of the electrolyte into the solid oxide and liquid fractions is prevented. This is of particular significance because it means that an electrolyte can be used which contains only the oxide fraction, a Li salt and a non-aqueous solvent for the Li-salt. It is not necessary to use either a separator or polymeric components to stabilize the electrolyte. In all cases enhanced conductivity due to percolation is obtained and the electrolyte has self healing properties. Its gel-like consistency prevents the two electrodes of a cell from contacting each other.

The 7 nm fumed SiO₂ (obtained from Sigma-Aldrich, Missouri USA) has a surface area BETₐᵣₑₐ=605.0 m²·g⁻¹ and a density of 2.438 g·cm⁻³.

Similarly, the 10 nm SiO₂ (non-fumed SiO2 obtained from Sigma-Aldrich, Missouri USA) has an approximate value for BETₐᵣₑₐ=537.9 m²·g⁻¹.

Measurements with electrolytes including SiO2 particles having a particle size of 300 nm (BETₐᵣₑₐ=8.2 m²·g⁻¹) were also conducted and were also seen to have a higher ionic conductivity than the pure electrolyte.

Although the above discussion has been given with respect to SiO2 as the oxide fraction, it is believed that other oxide fractions in a low volume range can also yield beneficial results. For example, for a 1M PEG-150 solution with an addition of a LiOTf (Lithium trifluoromethanesulfonate) salt and an Al₂O₃ oxide, which is preferably a fine grain powder with an approximate particle size which is less than 10 nm, typically in the range of 2 to 10 nm, a higher conductivity was found for volume fractions in the range from 0.5 vol. % to 6 vol. %. The maximum increase in ionic conductivity here was found to be approximately 1.3 times the ionic conductivity of the reference sample, however, these results were dependent on time.

### REFERENCES

Amita Chandra and Joachim Maier, Solid State Ionics 148, 153-158 (2002).
W. Wieczorek, Z. Florjanczyk and J. R. Stevens, Electrochim. Acta 40, 2251-2258 (1995).
Polymer electrolytes by F. Gray and M. Armand in Handbook of Battery Materials ed. By
J. O. Besenhard (Wiley-VCH, Weinheim, 1999)
Croce, F., Appetecchi, G. B., Persi, L. and Scrosati, B. Nanocomposite polymer electrolytes for lithium batteries. Nature 394, 456-458 (1998).
J. Maier, Prog. Solid. St. Chem. 23, 171-263 (1995).
Principles of ceramic processing by James S. Reed (John Wiley & Sons, New York, 1995)
Physical chemistry of surfaces by A. W. Adamson, (Fourth edition John Wiley & Sons, New York, 1982)
A. S. Best, S. Rajani and J. Schoonman; A. D' Epifanio, F. Serraino, B. Scrosati and F. Croce, Proc. Of 14^{th} International Conference on Solid State Ionics, Monterrey, Calif. (USA), Jun. 22-27, 2003.

1. A non-aqueous electrolyte including:
at least one ionically conducting salt,
a non-aqueous, anhydrous solvent for the ionically conductive salt, and at least one oxide in a particulate form, with a particle size below 2 μm, said oxide being selected such that it is not soluble in said solvent and such that it is water-free, said oxide being present as a solid phase in a solution formed by said ionically conductive salt in said solvent in an amount by volume in the range from 0.5 to 10% whereby percolation type behaviour arises with a pronounced increase in conductivity.

2. The non-aqueous electrolyte of claim 1, wherein said solvent is selected to achieve a degree of dissociation of the ionically conductive salt in the non-aqueous solvent, and wherein said degree of dissociation is a low degree of dissociation, with association constant in the range from 1×10⁻¹ to 10⁸/l⁻¹·mol⁻¹.

3. The non-aqueous electrolyte of claim 1, said electrolyte being disposed in a primary or secondary lithium battery having positive and negative electrodes, said oxide being selected such that it does not react with the material of either of said positive and negative electrodes.

4. The non-aqueous electrolyte of claim 1, when used in a supercapacitor.

5. The non-aqueous electrolyte in accordance with claim 1, wherein said ionically conductive salt comprises a salt selected from the group comprising Li(TFSI), LiPF₆ and LiClO₄, or a sodium salt or a silver salt.

6. The non-aqueous electrolyte of claim 1, wherein said non-aqueous, anhydrous solvent is selected from the group consisting of DME/EC, DEC/EC, DMC/EC, PC, DMSO, THF, AN and PEG.

7. The non-aqueous electrolyte in accordance with claim 1, wherein said oxide is selected from the group consisting of SiO₂, fumed SiO₂ and Al₂O₃.

8. The non-aqueous electrolyte in accordance with claim 1, wherein the fumed SiO₂ is produced from flame pyrolysis of silicon tetrachloride or from quartz sand vaporized in a high temperature electric arc, of e.g. 3000° C.

9. The non-aqueous electrolyte of claim 1, wherein the average particle size of the oxide is selected to be less than 300 nm.

10. The non-aqueous electrolyte of claim 1, wherein the average particle size of the oxide is selected in the size range from 2 to 15 nm.

11. The non-aqueous electrolyte of claim 1, wherein the oxide is present in the electrolyte in an amount and in a small particle size such as to give the electrolyte a consistency between that of a liquid and a solid.

12. The non-aqueous electrolyte of claim 1, wherein the oxide is present in the electrolyte in an amount by volume in the range from 0.5 to 6%.

13. The non-aqueous electrolyte of claim 1 wherein a heterogeneous doping effect is achieved consisting of one ion sort being absorbed and leading to said dissociation.

14. A battery comprising positive and negative electrodes and a non-aqueous electrolyte, said non-aqueous electrolyte including:
at least one ionically conducting salt,
a non-aqueous, anhydrous solvent for the ionically conductive salt, and at least one oxide in a particulate form, with a particle size below 2 μm, said oxide being selected such that it is not soluble in said solvent and such that it is water-free, said oxide being present as a solid phase in a solution formed by said ionically conductive salt in said solvent in an amount by volume in the range from 0.5 to 10% whereby percolation type behaviour arises with a pronounced increase in conductivity.

15. The battery of claim 14 wherein a heterogeneous doping effect is achieved consisting of one ion sort being absorbed and leading to said dissociation.

16. A supercapacitor comprising positive and negative electrodes and a non-aqueous electrolyte disposed between said electrodes, said non-aqueous electrolyte including:
at least one ionically conducting salt,
a non-aqueous, anhydrous solvent for the ionically conductive salt, and at least one oxide in a particulate form, with a particle size below 2 μm, said oxide being selected such that it is not soluble in said solvent and such that it is water-free, said oxide being present as a solid phase in a solution formed by said ionically conductive salt in said solvent in an amount by volume in the range from 0.5 to 10% whereby percolation type behaviour arises with a pronounced increase in conductivity.

17. The supercapacitor of claim 16 wherein a heterogeneous doping effect is achieved consisting of one ion sort being absorbed and leading to said dissociation.

18. An electro-chromic device including a non-aqueous electrolyte, said non-aqueous electrolyte including:
at least one ionically conducting salt,
a non-aqueous, anhydrous solvent for the ionically conductive salt, and at least one oxide in a particulate form, with a particle size below 2 μm, said oxide being selected such that it is not soluble in said solvent and such that it is water-free, said oxide being present as a solid phase in a solution formed by said ionically conductive salt in said solvent in an amount by volume in the range from 0.5 to 10% whereby percolation type behaviour arises with a pronounced increase in conductivity.

19. The electro-chromic device of claim 18 wherein a heterogeneous doping effect is achieved consisting of one ion sort being absorbed and leading to said dissociation.

20. A solar energy cell including a non-aqueous electrolyte, said non-aqueous electrolyte including:
at least one ionically conducting salt,
a non-aqueous, anhydrous solvent for the ionically conductive salt, and at least one oxide in a particulate form, with a particle size below 2 μm, said oxide being selected such that it is not soluble in said solvent and such that it is water-free, said oxide being present as a solid phase in a solution formed by said ionically conductive salt in said solvent in an amount by volume in the range from 0.5 to 10% whereby percolation type behaviour arises with a pronounced increase in conductivity.

21. The solar energy cell of claim 20 wherein a heterogeneous doping effect is achieved consisting of one ion sort being absorbed and
leading to said dissociation.
